(19) United States
(12) Patent Application Publication
(10) Pub. No.: US 2013/0271165 A1
(43) Pub. Date: Oct. 17, 2013

(54) OUTPUT IMPEDANCE TESTING DEVICE

(71) Applicants: HONG FU JIN PRECISION INDUSTRY (SHENZHEN) CO., LTD., Shenzhen (CN); HON HAI PRECISION INDUSTRY CO., LTD., New Taipei (TW)

(72) Inventors: PENG CHEN, Shenzhen (CN); SONG-LIN TONG, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/853,200

(22) Filed: Mar. 29, 2013

(30) Foreign Application Priority Data
Apr. 16, 2012 (CN) 201210109834.7

(51) Int. Cl. G01R 27/08

(52) U.S. Cl. CPC G01R 27/08
USPC 324/713

(57) ABSTRACT

A device that tests an output impedance of a voltage regulator module (VRM) includes a controller, a current regulating circuit, a voltage sampling circuit, and a current sampling circuit. The voltage sampling circuit samples an instantaneous alternating output voltage of the VRM, and outputs the instantaneous alternating output voltage to the controller. The current sampling circuit cooperates with the controller in sampling the instantaneous output current of the VRM. The controller controls the current regulating circuit to regulate the instantaneous output current of the VRM until the instantaneous alternating output voltage is about equal to a predetermined reference voltage, and calculates an output impedance of the VRM according to the instantaneous alternating output voltage and instantaneous output current when the instantaneous alternating output voltage is about equal to the predetermined reference voltage.

### BACKGROUND

1. Technical Field

The exemplary disclosure generally relates to output impedance testing devices, and particularly to an output impedance testing device for voltage regulator modules (VRMs).

2. Description of Related Art

A VRM is used for regulating voltage and outputting a regulated voltage to loads. In a circuit system having the VRM, an output impedance of the VRM needs to match a system impedance of the circuit system to maintain stability of the VRM. A typical way to get the output impedance of the VRM is by theoretical derivation. However, the theoretical derivation value of the output impedance of the VRM is usually not equal to an actual value of the output impedance when the VRM is in use. Setting the components of the VRM according to the theoretical derivation value of the output impedance is likely to decrease the stability of the VRM.

Therefore, there is room for improvement within the art.

### BRIEF DESCRIPTION OF THE DRAWINGS

Many aspects of the embodiments can be better understood with reference to the drawings. The components in the drawings are not necessarily drawn to scale, the emphasis instead being placed upon clearly illustrating the principles of the disclosure.

FIG. 1 shows a block diagram of an exemplary embodiment of an output impedance testing device comprising a controller, a current regulating circuit, a voltage sampling circuit, and a current sampling circuit.

FIG. 2 shows a circuit diagram of one embodiment of the controller and the current regulating circuit of the output impedance testing device shown in FIG. 1.

FIG. 3 shows a circuit diagram of one embodiment of the voltage sampling circuit of the output impedance testing device shown in FIG. 1.

FIG. 4 shows a circuit diagram of one embodiment of the current sampling circuit of the output impedance testing device shown in FIG. 1.

### DETAILED DESCRIPTION

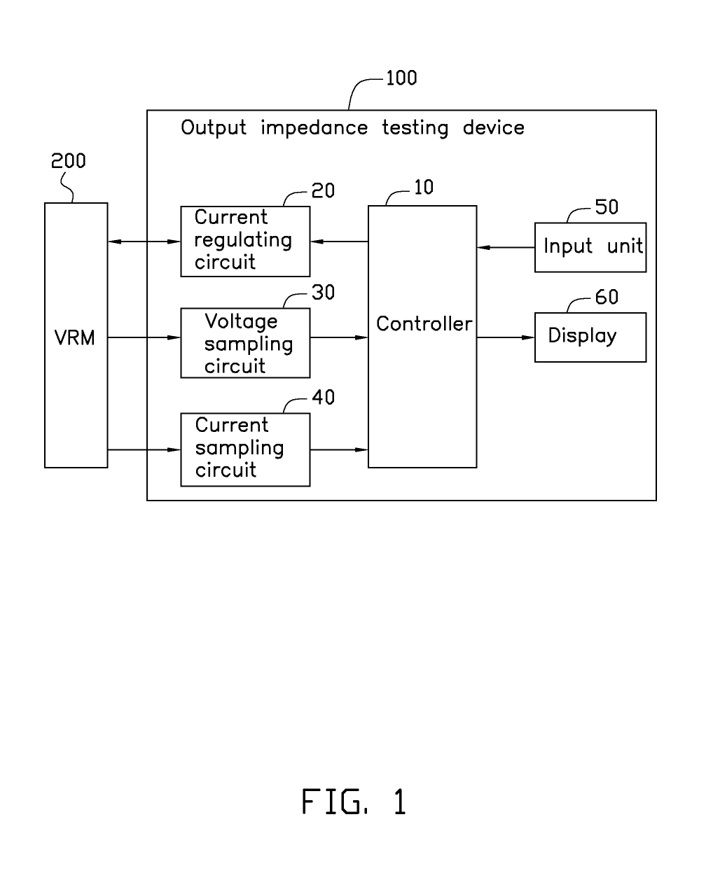

FIG. 1 shows a block diagram of an exemplary embodiment of a output impedance testing device 100 including a controller 10, a current regulating circuit 20, a voltage sampling circuit 30, a current sampling circuit 40, an input unit 50, and a display 60. The output impedance testing device 100 tests an output impedance of a voltage regulator module (VRM) 200.

The controller 10 is electronically connected to the current regulating circuit 20, the voltage sampling circuit 30, and the current sampling circuit 40. The controller 10 obtains an instantaneous alternating output voltage ΔV of the VRM 200 via the voltage sampling circuit 30, obtains an instantaneous output current ΔI of the VRM 200 via the current sampling circuit 40, and controls the current regulating circuit 20 to regulate the instantaneous output current ΔV of the VRM, until the instantaneous alternating output voltage ΔV is about equal to a predetermined reference voltage. At this time, the controller 10 calculates and outputs a quotient of the instantaneous alternating output voltage ΔV and the instantaneous output current ΔI, that is, the output impedance of the VRM. The predetermined reference voltage can be equal to a working voltage of a load driven by the VRM.

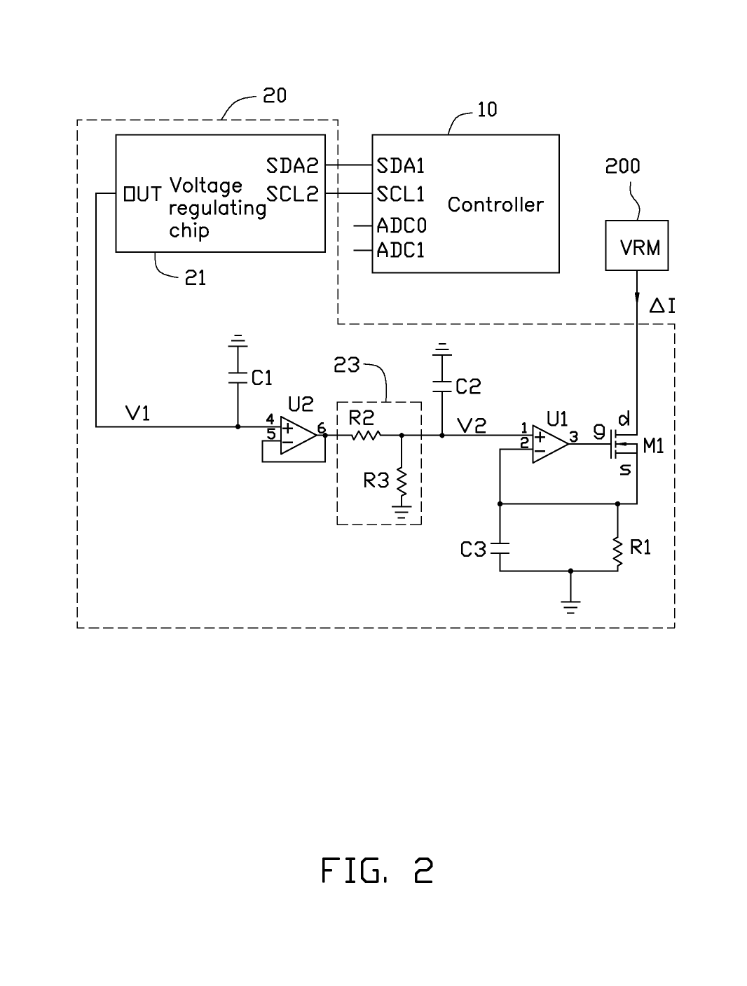

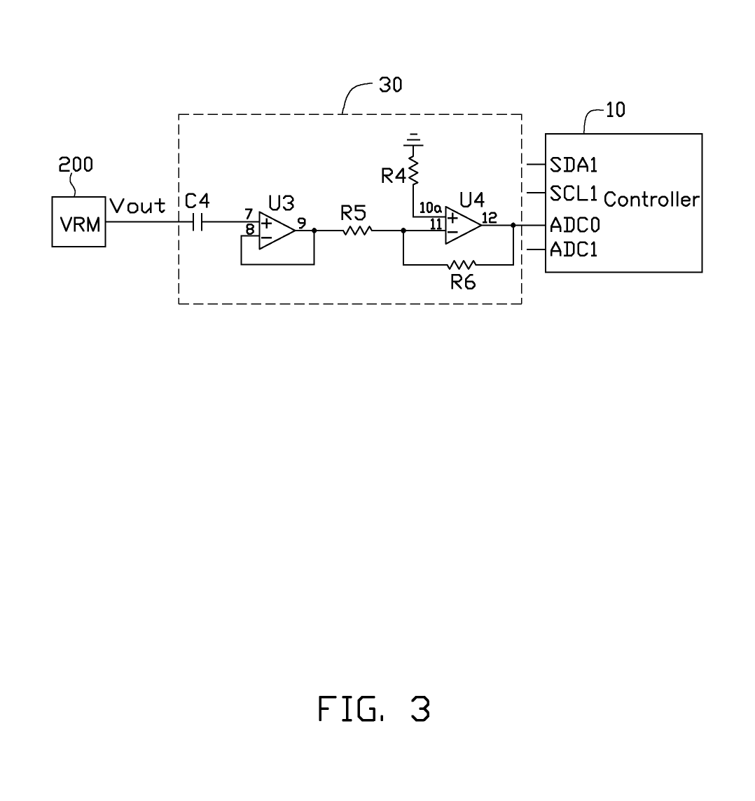

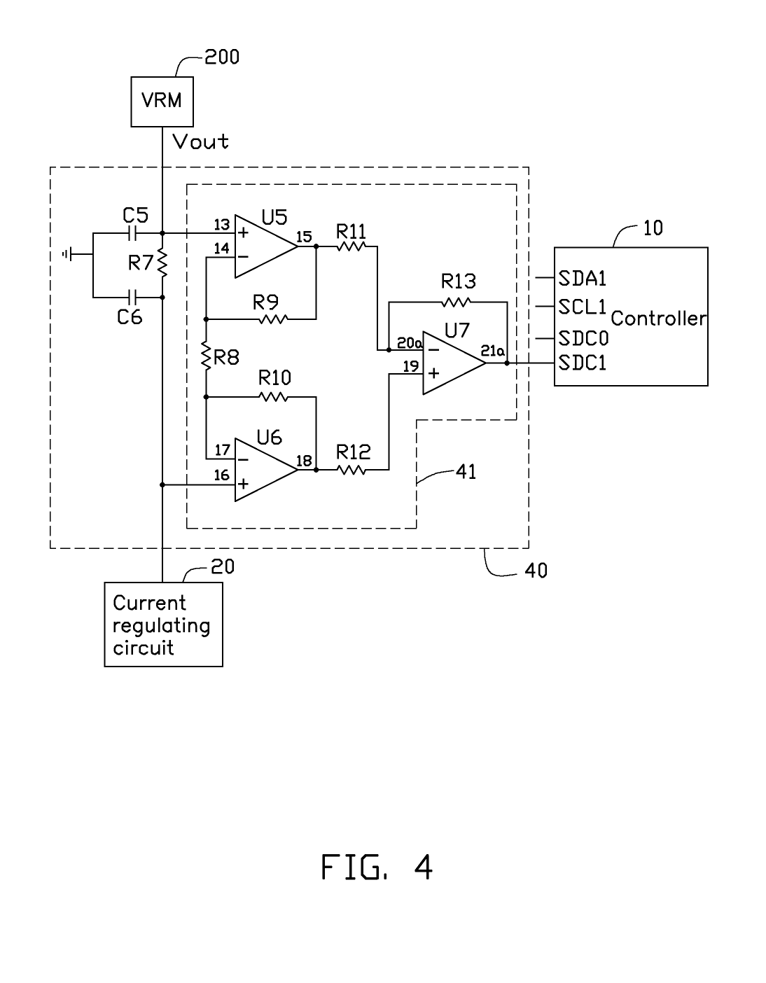

FIG. 2 shows a circuit diagram of one embodiment of the controller 10 and the current regulating circuit 20 of the output impedance testing device 100 shown in FIG. 1. The controller 10 includes a data pin SDA1, a clock pin SCL1, a voltage sampling data input pin ADC0, and a current sampling data input pin ADC1. The data pin SDA1 and the clock pin SCL1 are electronically connected to the current regulating circuit 20, to enable data communication between the controller 10 and the current regulating circuit 20. The voltage sampling data input pin ADC0 is electronically connected to the voltage sampling circuit 30 (see FIG. 3) to receive the instantaneous alternating output voltage ΔV from the voltage sampling circuit 30. The current sampling data input pin ADC1 is electronically connected to the current sampling circuit 40 (see FIG. 4) to receive the instantaneous output current ΔI from the current sampling circuit 40.

The current regulating circuit 20 includes a voltage regulating chip 21, a first operational amplifier U1, a second operational amplifier U2, an N-channel metal-oxide-semiconductor field-effect transistor (MOSFET) M1, a source resistor R1, a voltage dividing circuit 23, and three filtering capacitors C1-C3.

The voltage regulating chip 21 includes a data pin SDA2, a clock pin SCL2, and a voltage output pin OUT. The voltage regulating chip 21 regulates an output voltage V1 in response to data received by the data pin SDA2. The data pin SDA2 is electronically connected to the data pin SDA1 of the controller 10. The clock pin SCL2 is electronically connected to the clock pin SCL1 of the controller 10. The controller 10 controls the voltage regulating chip 21 to regulate the output voltage V1 by outputting data to the voltage regulating chip 21.

A non-inverting input terminal 4 of the second operational amplifier U2 is electronically connected to the voltage output pin OUT of the voltage regulating chip 21, and an output terminal 6 of the second operational amplifier U2 is electronically connected to an inverting input terminal 5 of the second operation amplifier U2 and a non-inverting input terminal 1 of the first operational amplifier U1. An inverting input terminal 2 of the first operational amplifier U1 is electronically connected to a source s of the N-channel MOSFET M1, and an output terminal 3 of the first operation amplifier U1 is electronically connected to a gate g of the N-channel MOSFET M1. A drain d of the N-channel MOSFET M1 is electronically connected to an output terminal of the VRM 200. A node between the inverting input terminal 2 of the first operational amplifier U1 and the source s of the N-channel MOSFET M1 is grounded via the source resistor R1. The voltage dividing circuit 23 includes a first voltage dividing resistor R2 and a second voltage dividing resistor R3 which are connected in series between the output terminal 6 of the second operational amplifier U2 and ground. The non-inverting input terminal 1 of the first operational amplifier U1 is electronically connected to a node between first and second voltage dividing resistors R2 and R3. The non-inverting input terminal 4 of the second operational amplifier U2, and the non-inverting input terminal 1 of the first operational amplifier U1 are grounded via the filtering capacitor C2, and the inverting input terminal 2 of the first operational amplifier U1 is grounded via the filtering capacitor C3.

The voltage dividing circuit 23 divides the output voltage V1 and outputs an input voltage Vo to the non-inverting input terminal 1 of the first operational amplifier U1. The input voltage Vo changes according to the output voltage V1.

The first operational amplifier U1 switches on the N-channel MOSFET M1, and changes current flowing through the N-channel MOSFET M1 according to the input voltage Vo. For example, the controller 10 controls the voltage regulating chip 21 to increase the output voltage V1, and the input voltage V2 is increased according to the increase of the output voltage V1. At this time, a driving current output from the output terminal 3 of the first operational amplifier U1 to the gate g is increased, with the current flowing to the drain d of the N-channel MOSFET M1, that is, the instantaneous output current ΔV of the VRM is correspondingly increased.

FIG. 3 shows a circuit diagram of one embodiment of the voltage sampling circuit 30 of the output impedance testing device 100 shown in FIG. 1. The output voltage Vout of the VRM 200 is substantially a direct current (DC) voltage with a minimal alternating voltage component. The voltage sampling circuit 30 samples the instantaneous alternating output voltage ΔV of the VRM 200 to achieve a good dynamic response and increased testing precision. The voltage sampling circuit 30 includes a DC insulation capacitor C4, a third operational amplifier U3, a fourth operational amplifier U4, and resistors R4-R6. The DC insulation capacitor C4 is electronically connected between the output terminal of the VRM 200 and a non-inverting input terminal 7 of the third operational amplifier U3. An inverting input terminal 8 and an output terminal 9 of the third operational amplifier U3 are connected. A non-inverting input terminal 10a of the fourth operational amplifier U4 is grounded via the resistor R4, an inverting input terminal 11 of the further operational amplifier U4 is electronically connected to the output terminal 9 of third operational amplifier U3 via the resistor R5, and an output terminal 12 of the fourth operational amplifier U4 is electronically connected to the inverting input terminal 11 via the resistor R6. The output terminal 12 is further electronically connected to the voltage sampling data input pin ADC0 of the controller 10.

The DC insulation capacitor C4 substantially reduces any DC component of the output voltage Vout of the VRM 200, and transmits the alternating voltage component of the output voltage Vout of the VRM 200 to the third operational amplifier U3. The fourth operational amplifier U4 amplifies alternating voltage component of the output voltage Vout, and outputs the amplified output voltage Vout to the controller 10. The controller 10 converts the amplified output voltage Vout to digital values, and calculates a quotient of the digital values and the amplification factor of the fourth operational amplifier U4, that is, the value of the instantaneous alternating output voltage ΔV.

FIG. 4 shows a circuit diagram of the current sampling circuit 40 of the output impedance testing device 100 shown in FIG. 1. The current sampling circuit 40 cooperates with the controller 10 in sampling the instantaneous output current ΔI. The current sampling circuit 40 includes a current detection resistor R7, two filtering capacitors C5 and C6, and a voltage sampling and amplifying unit 41. The current detection resistor R7 is electronically connected between the VRM 200 and the current regulating circuit 20. In particular, the current detection resistor R7 is electronically connected between the output terminal of the VRM 200 and the drain d of the N-channel MOSFEST M1 (not shown in FIG. 4) of the current regulating circuit 20. A node between the VRM 200 and the current detection resistor R7 is grounded via the filtering capacitor C5, and a node between the current regulating circuit 20 and the current detection resistor R7 is grounded via the filtering capacitor C6.

The voltage sampling and amplifying unit 41 samples the voltage across the current detection resistor R7, and amplifies the sampled voltage, then transmits the amplified voltage to the controller 10. In the exemplary embodiment, the voltage sampling and amplifying unit 41 includes a fifth operational amplifier U5, a sixth operational amplifier U6, a differential amplifier U7, a gain setting resistor R8, and resistors R9-R13. The current detection resistor R7 is further electronically connected between a non-inverting input terminal 13 of the fifth operational amplifier U5 and a non-inverting input terminal 16 of the sixth operational amplifier U6. An inverting input terminal 14 of the fifth operational amplifier U5 is electronically connected to an inverting input terminal 17 of the operational amplifier U6 via the gain setting resistor R8. An output terminal 15 of the fifth operational amplifier U5 is electronically connected to an inverting input terminal 20a of the differential amplifier U7 via the resistor R11, and an output terminal 18 of the sixth operational amplifier U6 is electronically connected to a non-inverting terminal 19 of the differential amplifier U7 via the resistor R12. The resistor R9 is electronically connected between the output terminal 15 and the inverting input terminal 14 of the fifth operational amplifier U5, the resistor R10 is electronically connected between the output terminal 18 and the inverting input terminal 17 of the sixth operational amplifier U6, and the resistor R13 is electronically connected between the output terminal 21a and the inverting input terminal 20a of the differential operational amplifier U7.

The fifth and sixth operational amplifiers U5 and U6 cooperate to form a pair of symmetrical non-inverting amplifiers, which amplify voltages on the two terminals of the current detection resistor R7, and transmit the amplified voltages to the inverting input terminal 20a and the non-inverting input terminal 19 of the differential amplifier U7. The differential amplifier U7 amplifies a difference between the voltages on the inverting and non-inverting input terminals 20a and 19, and then outputs the amplified voltage difference to the controller 10. The total amplification factor of the voltage sampling and amplifying unit 41 can be regulated by regulating the resistance of the gain setting resistor R8. The controller 10 converts the voltage output from the differential amplifier U7 to a digital value, and calculates the instantaneous output current ΔI according to the resistance of the current detection resistor R7 and the total amplification factor of the voltage sampling and amplifying unit 41.

The input unit 50 can include a plurality of keys (not shown) electronically connected to the controller 10. The input unit 50 is used to input the value of the predetermined reference voltage and an increment of the output voltage V1 of the voltage regulating chip 21. The controller 10 controls the voltage regulating chip 21 to regulate the output voltage V1 according to the incremental input from the input unit 50.

The display 60 displays the value of the predetermined reference voltage and the incremental input from the input unit 50, and the output impedance of the VRM 200 as calculated by the controller 10.

In use, the controller 10 receives the value of the predetermined reference voltage and the increment from the input unit 50, and controls the voltage regulating chip 21 to output the output voltage V1. At this time, the output voltage V1 preferably has a small value. The voltage sampling circuit 30 samples and outputs the instantaneous alternating output voltage ΔV to the controller 10, and the controller 10 determines whether the instantaneous alternating output voltage ΔV is equal to the predetermined reference voltage. If the instantaneous alternating output voltage ΔV is lower than the predetermined reference voltage, the controller 10 controls the voltage regulating chip 21 to regulate the output voltage V1 by the preset increments, until the instantaneous alternating output voltage ΔV is equal to the predetermined reference voltage. At this time, the controller 10 calculates the value of the output impedance of the VRM 200 according to the instantaneous alternating output voltage ΔV and the instantaneous output current ΔI, and the value of the output impedance of the VRM 200 is equal to a quotient of the instantaneous alternating output voltage ΔV and the instantaneous output current ΔI.

Since the current regulating circuit 20 can regulate the instantaneous output current ΔV of the VRM 200 under the control of the controller 10, to simulate a load that is powered by the VRM 200, the VRM 200 can respond dynamically. The controller 10 calculates the value of the output impedance of the VRM 200 according to the instantaneous alternating output voltage ΔV and the instantaneous output current ΔI, which achieves a more accurate measurement of the output impedance of the VRM 200.

It is believed that the exemplary embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. An device for testing an output impedance of a voltage regulator module (VRM), comprising:
a controller;
a current regulating circuit electronically connected to the controller and an output terminal of the VRM;
a voltage sampling circuit electronically connected to the controller and the output terminal of the VRM, the voltage sampling circuit sampling an instantaneous alternating output voltage of the VRM, and outputting the instantaneous alternating output voltage to the controller; and
a current sampling circuit electronically connected to the controller and the output terminal of the VRM, the current sampling circuit cooperating with the controller in sampling an instantaneous output current of the VRM;
wherein the controller controls the current regulating circuit to regulate the instantaneous output current of the VRM until the instantaneous alternating output voltage is about equal to a predetermined reference voltage, and calculates an output impedance of the VRM according to the instantaneous alternating output voltage and the instantaneous output current when the instantaneous alternating output voltage is about equal to the predetermined reference voltage.

2. The device of claim 1, wherein the output impedance of the VRM is about equal to a quotient of the instantaneous alternating output voltage and the instantaneous output current.

3. The device of claim 1, wherein the current regulating circuit comprises a voltage regulating chip, a first operational amplifier, an N-channel metal-oxide-semiconductor field-effect transistor (MOSFET), and a source resistor; the voltage regulating chip outputs an output voltage to a non-inverting input terminal of the first operational amplifier, and regulates the output voltage under the control of the controller; an inverting input terminal of the first operational amplifier is electronically connected to a source of the N-channel MOSFET, and an output terminal of the first operational amplifier is electronically connected to a gate of the N-channel MOSFET; a drain of the N-channel MOSFET is electronically connected to the output terminal of the VRM; a node between the inverting input terminal of the first operational amplifier and the source of the N-channel MOSFET is grounded via the source resistor; the first operational amplifier switches on the N-channel MOSFET, and regulates a current flowing through the N-channel MOSFET according to the output voltage output from the voltage regulating chip, thereby regulating the instantaneous output current of the VRM.

4. The device of claim 3, wherein the current regulating circuit further comprises a second operational amplifier, and a filtering capacitor; a non-inverting input terminal is electronically connected to an output terminal of the voltage regulating chip, an output terminal of the second operational amplifier is electronically connected to an inverting input terminal of the second operational amplifier and the non-inverting input terminal of the first operational amplifier; a node between the output terminal of the voltage regulating chip and the non-inverting input terminal of the second operational amplifier is grounded via the filtering capacitor.

5. The device of claim 4, wherein the current regulating circuit further comprises a voltage dividing circuit comprising a first voltage dividing resistor and a second voltage dividing resistor that are connected in series between the output terminal of the second operational amplifier and ground, a node between the first and second voltage dividing resistors is electronically connected to the non-inverting input terminal of the first operational amplifier.

6. The device of claim 1, wherein the voltage sampling circuit comprises a direct current insulation capacitor, a third operational amplifier, and s fourth operational amplifier; the direct current insulation capacitor is electronically connected between the output terminal of the VRM and a non-inverting input terminal of the third operational amplifier; an inverting input terminal and an output terminal of the third operational amplifier are electronically interconnected; a non-inverting input terminal of the fourth operational amplifier is grounded, an inverting input terminal of the fourth operational amplifier is electronically connected to the output terminal of the third operational amplifier and an output terminal of the fourth operational amplifier, the output terminal of the fourth operational amplifier is electronically connected to the controller; the direct current insulation capacitor reduces a direct voltage component of an output voltage of the VRM and transmit an alternative component of the output voltage of the VRM to the third operation amplifier; the fourth operational amplifier amplifies alternating voltage component and outputs the amplified output voltage to the controller.

7. The device of claim 1, wherein the current sampling circuit comprises a current detection resistor, and a voltage sampling and amplifying unit, the current detection resistor is electronically connected between the output terminal of the VRM and the current regulation circuit; the voltage sampling and amplifying unit samples a voltage across the current detection resistor, and amplifying the voltage across the current detection resistor that is then transmitted to the controller; the controller calculates the instantaneous output current of the VRM according to the resistance of the current detection resistor and an amplification factor of the voltage sampling and the amplifying unit.

8. The device of claim 7, wherein the voltage sampling and amplifying circuit comprises a fifth operational amplifier, a sixth operational amplifier, a differential amplifier, and a gain setting resistor; the current detection resistor is electronically connected between non-inverting input terminals of the fifth and sixth operational amplifiers, an inverting input terminal of the fifth operational amplifier is electronically connected to an inverting input terminal of the sixth operational amplifier via the gain setting resistor, an output terminal of the fifth operational amplifier is electronically connected to an inverting input terminal of the differential amplifier, and an output terminal of the sixth operational amplifier is electronically connected to a non-inverting input terminal of the differential amplifier.

9. The device of claim 7, wherein the current sampling circuit further comprises a second filtering capacitor and a third filtering capacitor, a node between the current detection resistor an the VRM is grounded via the second filtering capacitor; and a node between the current detection resistor and the current regulating circuit is grounded via the third filtering capacitor.

10. The device of the claim 3, further comprising an input unit electronically connected to the controller, wherein the input unit inputs a value of the predetermined reference voltage, and an incremental of the output voltage of the voltage regulating chip.

11. An device for testing an output impedance of a voltage regulator module (VRM), comprising:
a controller;
a current regulating circuit electronically connected to the controller and an output terminal of the VRM, the current regulating circuit simulating a load driven by the VRM;
a voltage sampling circuit electronically connected to the controller and the output terminal of the VRM, the voltage sampling circuit sampling an instantaneous alternating output voltage of the VRM, and outputting the instantaneous alternating output voltage to the controller; and
a current sampling circuit electronically connected to the controller and the output terminal of the VRM, the current sampling circuit cooperating with the controller in sampling an instantaneous output current of the VRM;
wherein the controller controls the current regulating circuit to regulate the instantaneous output current of the VRM to make the VRM to execute dynamic response until the instantaneous alternating output voltage is equal to a predetermined reference voltage, and calculates an output impedance of the VRM according to the instantaneous alternating output voltage and instantaneous output current when the instantaneous alternating output voltage is equal to the predetermined reference voltage.

12. The device of claim 11, wherein the output impedance of the VRM is equal to a quotient of the instantaneous alternating output voltage and instantaneous output current.

13. The device of claim 11, wherein the current regulating circuit comprises a voltage regulating chip, a first operational amplifier, an N-channel metal-oxide-semiconductor field-effect transistor (MOSFET), and a source resistor; the voltage regulating chip outputs an output voltage to a non-inverting input terminal of the first operational amplifier, and regulates the output voltage under the control of the controller; an inverting input terminal of the first operational amplifier is electronically connected to a source of the N-channel MOSFET, and an output terminal of the first operational amplifier is electronically connected to a gate of the N-channel MOSFET; a drain of the N-channel MOSFET is electronically connected to the output terminal of the VRM; a node between the inverting input terminal of the first operational amplifier and the source of the N-channel MOSFET is grounded via the source resistor; the first operational amplifier switches on the N-channel MOSFET, and regulates a current flowing through the N-channel MOSFET according to the output voltage output from the voltage regulating chip, thereby regulating the instantaneous output current of the VRM.

14. The device of claim 13, wherein the current regulating circuit further comprises a second operational amplifier, and a filtering capacitor; a non-inverting input terminal is electronically connected to an output terminal of the voltage regulating chip, an output terminal of the second operational amplifier is electronically connected to an inverting input terminal of the second operational amplifier and the non-inverting input terminal of the first operational amplifier; a node between the output terminal of the voltage regulating chip and the non-inverting input terminal of the second operational amplifier is grounded via the filtering capacitor.

15. The device of claim 14, wherein the current regulating circuit further comprises a voltage dividing circuit comprising a first voltage dividing resistor and a second voltage dividing resistor that are connected in series between the output terminal of the second operational amplifier and ground, a node between the first and second voltage dividing resistors is electronically connected to the non-inverting input terminal of the first operational amplifier.

16. The device of claim 11, wherein the voltage sampling circuit comprises a direct current insulation capacitor, a third operational amplifier, and s fourth operational amplifier; the direct current insulation capacitor is electronically connected between the output terminal of the VRM and a non-inverting input terminal of the third operational amplifier; an inverting input terminal and an output terminal of the third operational amplifier are electronically interconnected; a non-inverting input terminal of the fourth operational amplifier is grounded, an inverting input terminal of the fourth operational amplifier is electronically connected to the output terminal of the third operational amplifier and an output terminal of the fourth operational amplifier, the output terminal of the fourth operational amplifier is electronically connected to the controller; the direct current insulation capacitor eliminates a direct voltage component of an output voltage of the VRM and transmit an alternative component of the output voltage of the VRM to the third operation amplifier; the fourth operational amplifier amplifies alternating voltage component and outputs the amplified output voltage to the controller.

17. The device of claim 11, wherein the current sampling circuit comprises a current detection resistor, and a voltage sampling and amplifying unit, the current detection resistor is electronically connected between the output terminal of the VRM and the current regulation circuit; the voltage sampling and amplifying unit samples a voltage across the current detection resistor, and amplifying the voltage across the current detection resistor that is then transmitted to the controller; the controller calculates the instantaneous output current of the VRM according to the resistance of the current detection resistor and an amplification factor of the voltage sampling and amplifying unit.

18. The device of claim 17, wherein the voltage sampling and amplifying circuit comprises a fifth operational amplifier, a sixth operational amplifier, a differential amplifier, and a gain setting resistor; the current detection resistor is electronically connected between non-inverting input terminals of the fifth and sixth operational amplifiers; an inverting input terminal of the fifth operational amplifier is electronically connected to an inverting input terminal of the sixth operational amplifier via the gain setting resistor, an output terminal of the fifth operational amplifier is electronically connected to an inverting input terminal of the differential amplifier, and an output terminal of the sixth operational amplifier is electronically connected to a non-inverting input terminal of the differential amplifier.

19. The device of claim 17, wherein the current sampling circuit further comprises a second filtering capacitor and a third filtering capacitor, a node between the current detection resistor an the VRM is grounded via the second filtering capacitor; and a node between the current detection resistor and the current regulating circuit is grounded via the third filtering capacitor.

20. The device of the claim 13, further comprising an input unit electronically connected to the controller, wherein the input unit inputs a value of the predetermined reference voltage, and an incremental of the output voltage of the voltage regulating chip.
